(19) United States
(12) Patent Application Publication
(10) Pub. No.: US 2024/0429033 A1
(43) Pub. Date: Dec. 26, 2024

(54) PLASMA PROCESSING APPARATUS AND PLASMA PROCESSING METHOD

(71) Applicant: Tokyo Electron Limited, Tokyo (JP)

(72) Inventor: Chishio KOSHIMIZU, Miyagi (JP)

(73) Assignee: Tokyo Electron Limited, Tokyo (JP)

(21) Appl. No.: 18/825,163

(22) Filed: Sep. 5, 2024

Related U.S. Application Data
(63) Continuation of application No. PCT/JP2023/008388, filed on Mar. 6, 2023.

(30) Foreign Application Priority Data
Mar. 18, 2022 (JP) 2022-043524

(51) Int. Cl. H01J 37/32

(52) U.S. Cl. CPC H01J 37/32834; H01J 37/32128; H01J 2237/2007

(57) ABSTRACT

A plasma processing apparatus disclosed herein includes a first baffle plate and a second baffle plate. The first baffle plate and the second baffle plate are disposed between a processing space and an exhaust space in a chamber. The second baffle plate is provided downstream of the first baffle plate in a flow of gas in the chamber. In at least a partial period of a waveform cycle of an electric bias energy periodically applied to a substrate support in the chamber, a value of a voltage that is applied to the second baffle plate is higher than a value of a voltage that is applied to the first baffle plate.

### CROSS-REFERENCE TO RELATED APPLICATIONS

This application is a bypass continuation application of international application No. PCT/JP2023/008388 having an international filing date of Mar. 6, 2023 and designating the United States, the international application being based upon and claiming the benefit of priority from Japanese Patent Application No. 2022-043524, filed on Mar. 18, 2022, the entire contents of each are incorporated herein by reference.

### TECHNICAL FIELD

Exemplary embodiments of the present disclosure relate to a plasma processing apparatus and a plasma processing method.

### BACKGROUND

A plasma processing apparatus is used for plasma processing on a substrate. The plasma processing apparatus includes a chamber, a substrate support, and a baffle plate. The substrate support is provided in the chamber. The baffle plate is provided between the substrate support and a sidewall of the chamber. The baffle plate is interposed between a processing space and an exhaust space, and is provided with a plurality of through-holes.

### CITATION LIST

### Patent Documents

Patent Document 1: JP2010-003958A

### SUMMARY

The present disclosure provides a technique for suppressing diffusion of charged particles from a processing space in a chamber into an exhaust space in the chamber.

In an exemplary embodiment, a plasma processing apparatus is provided. The plasma processing apparatus includes a chamber, a substrate support, a plasma generator, a bias power supply, a first baffle plate, a second baffle plate, a first power supply, and a second power supply. The substrate support is provided in the chamber. The plasma generator is configured to generate plasma from a gas within the chamber. The bias power supply is configured to periodically supply an electric bias energy having a waveform cycle to the substrate support. The first baffle plate and the second baffle plate are disposed in the chamber. The first power supply is electrically connected to the first baffle plate. The second power supply is electrically connected to the second baffle plate. The first baffle plate is disposed between a processing space in the chamber in which a substrate disposed on the substrate support is processed and the second baffle plate. The second baffle plate is disposed between an exhaust space in the chamber to which an exhaust system is connected and the first baffle plate. In at least a partial period in the waveform cycle, a value of a voltage that is applied to the second baffle plate by the second power supply is higher than a value of a voltage that is applied to the first baffle plate by the first power supply.

According to the exemplary embodiment, the technique for suppressing the diffusion of the charged particles from the processing space in the chamber into the exhaust space in the chamber is provided.

### BRIEF DESCRIPTION OF DRAWINGS

FIG. 1 is a view illustrating an example of a configuration of a plasma processing system.

FIG. 2 is a view illustrating an example of a configuration of a capacitively-coupled plasma processing apparatus.

FIG. 3 is a view illustrating an example of connection between a first power supply and a second power supply.

FIG. 4 is a view illustrating another example of the first power supply and the second power supply.

FIG. 5 is a view illustrating another example of the first power supply and the second power supply.

FIG. 6A is a timing chart relating to the plasma processing apparatus according to the exemplary embodiment.

FIG. 6B is a timing chart relating to the plasma processing apparatus according to the exemplary embodiment.

FIG. 6C is a timing chart relating to the plasma processing apparatus according to the exemplary embodiment.

FIG. 7A is a timing chart relating to the plasma processing apparatus according to the exemplary embodiment.

FIG. 7B is a timing chart relating to the plasma processing apparatus according to the exemplary embodiment.

FIG. 7C is a timing chart relating to the plasma processing apparatus according to the exemplary embodiment.

FIG. 7D is a timing chart relating to the plasma processing apparatus according to the exemplary embodiment.

FIG. 8A is a timing chart relating to the plasma processing apparatus according to the exemplary embodiment.

FIG. 8B is a timing chart relating to the plasma processing apparatus according to the exemplary embodiment.

FIG. 9 is a flowchart of a plasma processing method according to an exemplary embodiment.

### DETAILED DESCRIPTION

Hereinafter, various exemplary embodiments will be described.

In an exemplary embodiment, a plasma processing apparatus is provided. The plasma processing apparatus includes a chamber, a substrate support, a plasma generator, a bias power supply, a first baffle plate, a second baffle plate, a first power supply, and a second power supply. The substrate support is provided in the chamber. The plasma generator is configured to generate plasma from a gas within the chamber. The bias power supply is configured to periodically supply an electric bias energy having a waveform cycle to the substrate support. The first baffle plate and the second baffle plate are disposed in the chamber. The first power supply is electrically connected to the first baffle plate. The second power supply is electrically connected to the second baffle plate. The first baffle plate is disposed between a processing space in the chamber in which a substrate disposed on the substrate support is processed and the second baffle plate. The second baffle plate is disposed between an exhaust space in the chamber to which an exhaust system is connected and the first baffle plate. In at least a partial period in the waveform cycle, a value of a voltage that is applied to the second baffle plate by the second power supply is higher than a value of a voltage that is applied to the first baffle plate by the first power supply.

When a potential of the second baffle plate is higher than a potential of the first baffle plate, a flow of positive ions from the plasma in the processing space from the first baffle plate toward the second baffle plate is suppressed. Therefore, according to the embodiment, it is possible to suppress diffusion of charged particles from the processing space in the chamber into the exhaust space in the chamber.

In the exemplary embodiment, in an entirety of the waveform cycle, the value of the voltage that is applied to the second baffle plate by the second power supply may be higher than the value of the voltage that is applied to the first baffle plate by the first power supply.

In the exemplary embodiment, the waveform cycle may include a positive phase period in which the potential of the substrate is higher than an average potential of the substrate in the waveform cycle, and a negative phase period in which the potential of the substrate is lower than the average potential. In the negative phase period, the value of the voltage that is applied to the second baffle plate by the second power supply may be higher than the value of the voltage that is applied to the first baffle plate by the first power supply.

In the exemplary embodiment, the value of the voltage that is applied to the second baffle plate by the second power supply may be constant.

In the exemplary embodiment, the waveform cycle may include a positive phase period in which the potential of the substrate is higher than an average potential of the substrate in the waveform cycle, and a negative phase period in which the potential of the substrate is lower than the average potential. In the positive phase period, the value of the voltage that is applied to the second baffle plate by the second power supply is higher than the value of the voltage that is applied to the first baffle plate by the first power supply.

In the exemplary embodiment, the value of the voltage that is applied to the first baffle plate by the first power supply may be constant.

In the exemplary embodiment, the chamber may be grounded. In the waveform cycle, a potential of the second baffle plate may be higher than a potential of the chamber.

In the exemplary embodiment, the first baffle plate and the second baffle plate may extend between an outer periphery of the substrate support and a sidewall of the chamber. In the exemplary embodiment, at least one of the first baffle plate and the second baffle plate may be movable.

In the exemplary embodiment, the electric bias energy may be a bias radio-frequency power having a frequency that is a reciprocal of a time length of the waveform cycle, or is a pulse of a voltage that is applied to the substrate support at a time interval equal to the time length of the waveform cycle.

In another exemplary embodiment, a plasma processing method is provided. The plasma processing method includes generating plasma in a chamber of a plasma processing apparatus. The plasma processing method further includes supplying an electric bias energy having a waveform cycle to a substrate support disposed in the chamber. The plasma processing method further includes applying a voltage to each of a first baffle plate and a second baffle plate disposed in the chamber. The first baffle plate is disposed between a processing space in the chamber in which a substrate disposed on the substrate support is processed and the second baffle plate. The second baffle plate is disposed between an exhaust space in the chamber to which an exhaust system is connected and the first baffle plate. In at least a partial period in the waveform cycle, a value of the voltage that is applied to the second baffle plate is higher than a value of the voltage that is applied to the first baffle plate.

Hereinafter, various exemplary embodiments will be described in detail with reference to the drawings. Further, like reference numerals will be given to like or corresponding parts throughout the drawings.

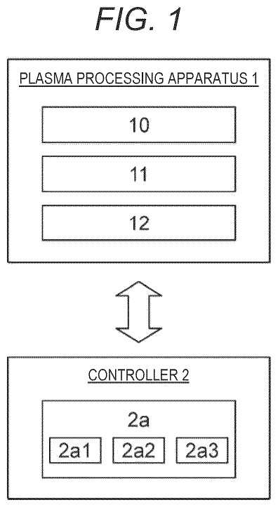

FIG. 1 is a diagram for explaining an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like.

The controller 2 processes computer-executable instructions for instructing the plasma processing apparatus 1 to execute various steps described herein below. The controller 2 may be configured to control the respective elements of the plasma processing apparatus 1 to execute the various steps described herein below. In an embodiment, part or all of the controller 2 may be included in the plasma processing apparatus 1. The controller 2 may include a processor 2al, a storage 2a2, and a communication interface 2a3. The controller 2 is implemented by, for example, a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, and is read from the storage 2a2 and executed by the processor 2a1. The medium may be various storing media readable by the computer 2a, or may be a communication line connected to the communication interface 2a3. The processor 2a1 may be a Central Processing Unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

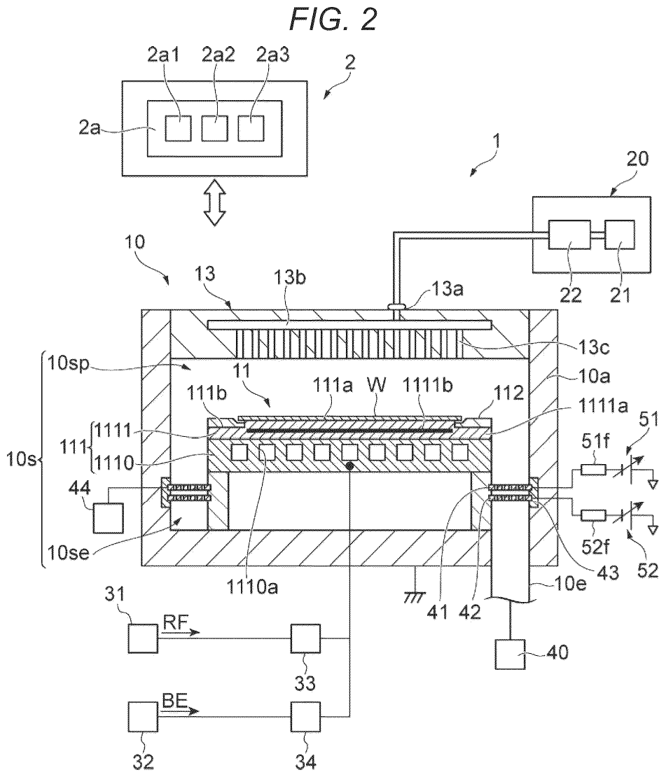

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, and the exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has an interior space 10s defined by the shower head 13, a sidewall 10a of the plasma processing chamber 10, and the substrate support 11. The interior space 10s includes a processing space 10sp and an exhaust space 10se. The plasma processing chamber 10 is grounded. The substrate support 11 is electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the processing space 10sp. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the processing space 10sp from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The exhaust system 40 may be connected to, for example, a gas exhaust port 10e disposed at a bottom portion of the plasma processing chamber 10. The gas exhaust port 10e is connected to the exhaust space 10se. The exhaust system 40 is connected to the processing space 10sp via the exhaust space 10se. The exhaust system 40 may include a pressure adjusting valve and a vacuum pump. A pressure in the interior space 10s is adjusted by the pressure adjusting valve. The vacuum pump may include a turbo molecular pump, a dry pump, or a combination thereof.

The plasma processing apparatus 1 further includes a radio-frequency power supply 31 and a bias power supply 32. The radio-frequency power supply 31 constitutes the plasma generator 12 according to one embodiment. The radio-frequency power supply 31 is configured to generate a source radio-frequency power RF. The source radio-frequency power RF has a source frequency f_{RF}. The source frequency f_{RF} may be a frequency in a range of 10 MHz to 150 MHz. The radio-frequency power supply 31 is electrically connected to a radio-frequency electrode via a matcher 33, and is configured to supply the source radio-frequency power RF to the radio-frequency electrode. The radio-frequency electrode may be the conductive member of the base 1110, at least one electrode provided in the ceramic member 1111a, or the upper electrode. When the source radio-frequency power RF is supplied to the radio-frequency electrode, the plasma is generated from the gas in the chamber 10.

The matcher 33 has a variable impedance. The variable impedance of the matcher 33 is set to reduce reflection of the source radio-frequency power RF from a load. The matcher 33 may be controlled by the controller 2, for example.

The bias power supply 32 is configured to generate electric bias energy BE. The bias power supply 32 is electrically coupled to the substrate support 11. The bias power supply 32 is electrically connected to a bias electrode in the substrate support 11, and is configured to supply the electric bias energy BE to the bias electrode. The bias electrode may be the conductive member of the base 1110 or at least one electrode provided in the ceramic member 1111a. When the electric bias energy BE is supplied to the bias electrode, the ions from the plasma are attracted to the substrate W.

The electric bias energy BE has a bias frequency. The bias frequency is lower than the source frequency. The bias frequency may be a frequency in a range of 100 kHz to 60 MHz. Further, the electric bias energy BE has a waveform cycle CY. The waveform cycle CY has a time length that is the reciprocal of the bias frequency. The electric bias energy BE is periodically supplied to the bias electrode in the waveform cycle CY (time interval).

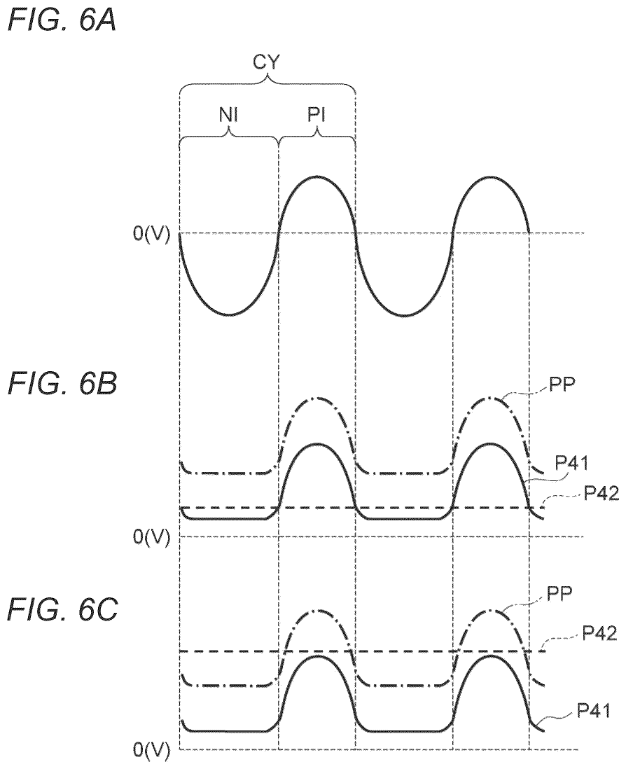

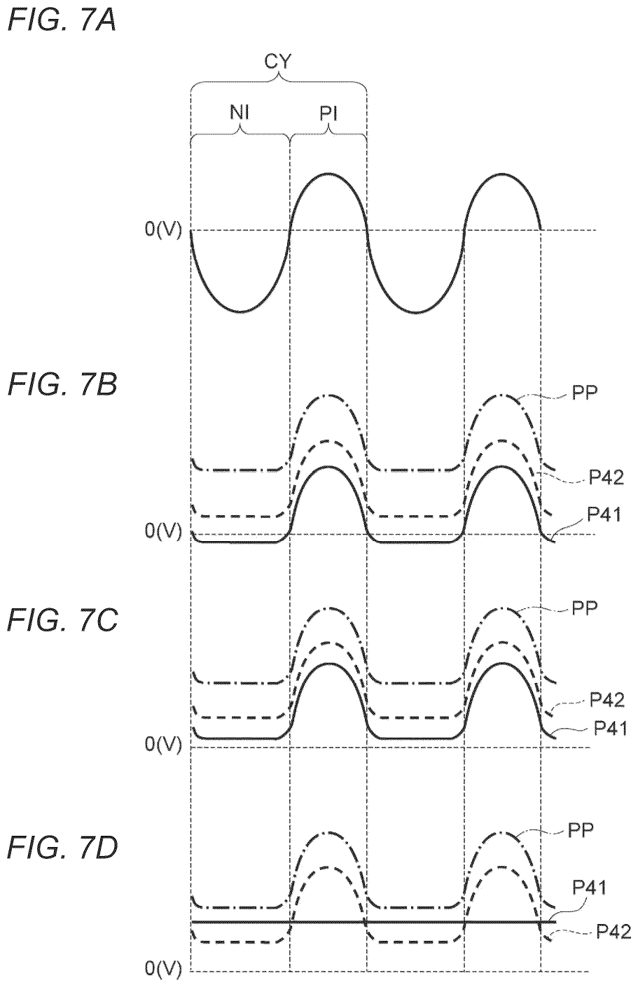

The electric bias energy BE may be a bias radio-frequency power having the bias frequency (see FIGS. 6A and 7A). That is, the electric bias energy BE may have a sinusoidal waveform whose frequency is the bias frequency. In this case, the bias power supply 32 is electrically connected to the bias electrode via a matcher 34. The variable impedance of the matcher 34 is set to reduce reflection of the bias radio-frequency power LF from the load.

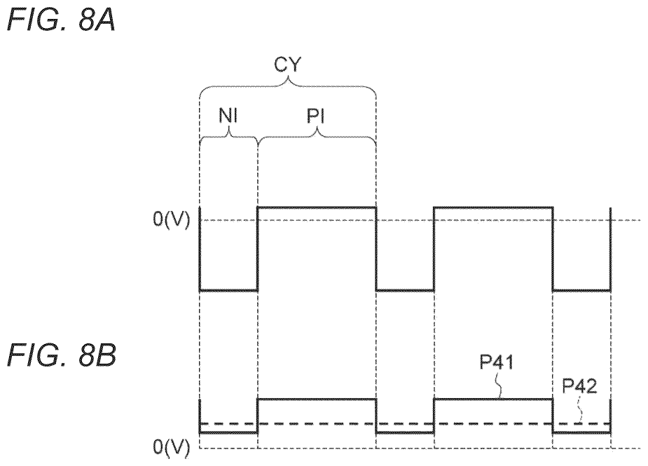

Alternatively, the electric bias energy BE may include a pulse of the voltage (see FIG. 8A). The pulse of the voltage is applied to the bias electrode in the waveform cycle CY. The pulse of the voltage is periodically applied to the bias electrode at time intervals of a length equal to the time length of the waveform cycle CY. The waveform of the pulse of the voltage may be a rectangular wave, a triangular wave, or any waveform. The polarity of the pulse of the voltage is set such that the ions from the plasma can be attracted into the substrate W by generating a potential difference between the substrate W and the plasma. The pulse of the voltage may be, for example, a pulse of a negative voltage. When the electric bias energy BE is the pulse of the voltage, the plasma processing apparatus 1 need not include the matcher 34.

The plasma processing apparatus 1 further includes a first baffle plate 41 and a second baffle plate 42. Each of the first baffle plate 41 and the second baffle plate 42 include a plurality of through-holes. The first baffle plate 41 and the second baffle plate 42 are provided in the chamber 10. The first baffle plate 41 is disposed between the processing space 10sp and the second baffle plate 42. The processing space 10sp is a space in the chamber 10 in which the substrate W disposed on the substrate support 11 is processed. The second baffle plate 42 is disposed between the exhaust space 10se and the first baffle plate 41. The exhaust space 10se is a space inside the chamber 10 to which the exhaust system 40 is connected. That is, the first baffle plate 41 is provided upstream of the second baffle plate 42 in a flow of the gas in the chamber 10. The second baffle plate 42 is provided downstream of the first baffle plate 41.

In one embodiment, as illustrated in FIG. 2, the first baffle plate 41 and the second baffle plate 42 extend between an outer periphery of the substrate support 11 and the sidewall of the chamber 10, and extend in a circumferential direction around the substrate support 11. An outer edge of each of the first baffle plate 41 and the second baffle plate 42 is supported by an insulating member 43. An inner edge of each of the first baffle plate 41 and the second baffle plate 42 is supported by an insulating member of the substrate support 11.

In one embodiment, at least one of the first baffle plate 41 and the second baffle plate 42 may be movable. In this embodiment, the plasma processing apparatus 1 further includes a driving unit 44. The driving unit 44 moves at least one of the first baffle plate 41 and the second baffle plate 42 to change a relative position between the first baffle plate 41 and the second baffle plate 42. The driving unit 44 may move at least one of the first baffle plate 41 and the second baffle plate 42 to change a distance between the first baffle plate 41 and the second baffle plate 42. The driving unit 44 may rotate at least one of the first baffle plate 41 and the second baffle plate 42 around a central axis. The driving unit 44 may include a motor or a hydraulic or air pressure cylinder.

The plasma processing apparatus 1 further includes a first power supply 51 and a second power supply 52. The first power supply 51 and the second power supply 52 are, for example, variable direct-current power supplies. The first power supply 51 is electrically connected to the first baffle plate 41. The second power supply 52 is electrically connected to the second baffle plate 42. Specifically, one electrode (for example, a negative electrode) of the first power supply 51 is electrically connected to the first baffle plate 41 via a filter 51f. One electrode (for example, a negative electrode) of the second power supply 52 is electrically connected to the second baffle plate 42 via a filter 52f. Each of the filters 51f and 52f is an electric filter that blocks or reduces the radio-frequency power. The other electrode (for example, a positive electrode) of each of the first power supply 51 and the second power supply 52 is connected to the ground.

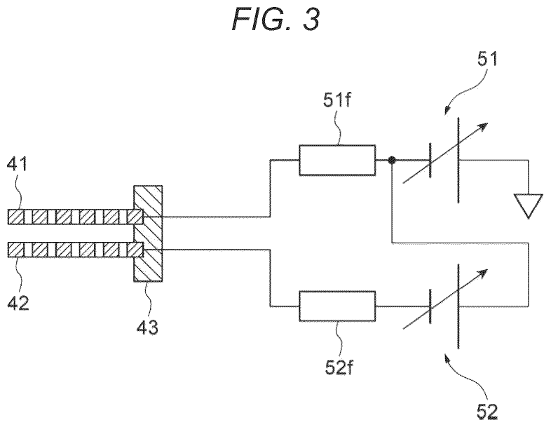

Here, reference will be made to FIG. 3. FIG. 3 is a view illustrating an example of the connection between the first power supply and the second power supply. As illustrated in FIG. 3, the other electrode (for example, the positive electrode) of the second power supply 52 may be connected to one electrode (for example, the negative electrode) of the first power supply 51.

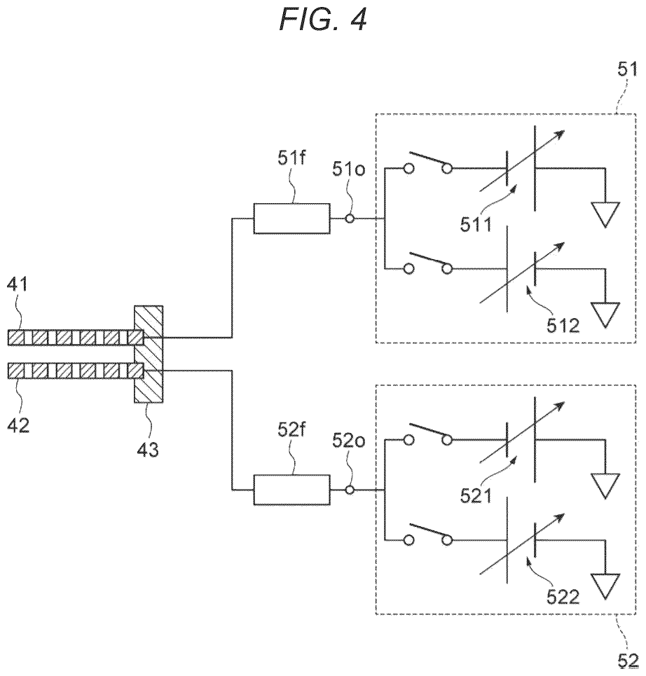

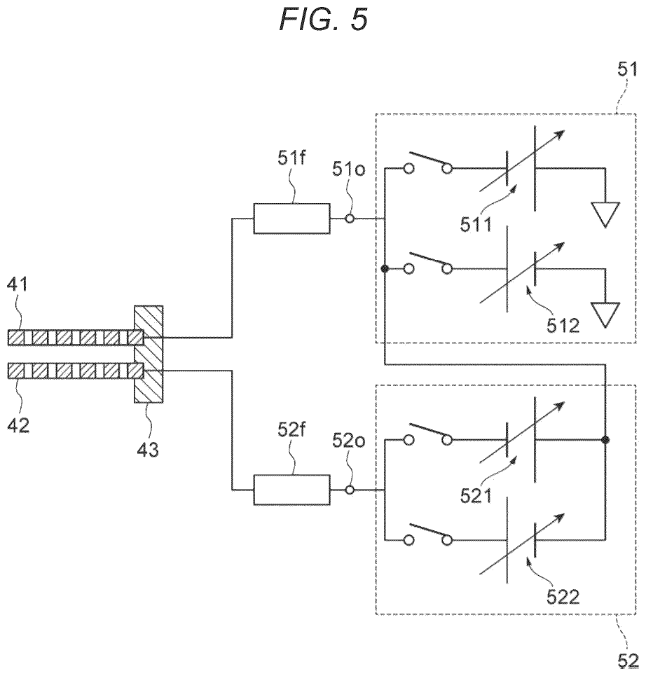

Hereinafter, reference will be made to FIGS. 4 and 5. FIGS. 4 and 5 are views illustrating other examples of the first power supply and the second power supply. In the examples illustrated in FIGS. 4 and 5, the first power supply 51 includes a power supply 511 and a power supply 512. The second power supply 52 includes a power supply 521 and a power supply 522. The power supply 511, the power supply 512, the power supply 521, and the power supply 522 are, for example, variable direct-current power supplies. The negative electrode of the power supply 511 is connected to an output 51o of the first power supply 51 via a switch. The positive electrode of the power supply 511 is connected to the ground. The positive electrode of the power supply 512 is connected to the output 51o of the first power supply 51 via a switch. The negative electrode of the power supply 512 is connected to the ground. The output 51o of the first power supply 51 is connected to the first baffle plate 41 via the filter 51f. The negative electrode of the power supply 521 is connected to an output 52o of the second power supply 52 via a switch. The positive electrode of the power supply 522 is connected to the output 52o of the second power supply 52 via a switch. The output 52o of the second power supply 52 is connected to the second baffle plate 42 via the filter 52f. In the example illustrated in FIG. 4, the positive electrode of the power supply 521 and the negative electrode of the power supply 512 are connected to the ground. In the example illustrated in FIG. 5, the positive electrode of the power supply 521 and the negative electrode of the power supply 522 are connected to the output 51o of the first power supply 51. In the examples illustrated in FIGS. 4 and 5, the first power supply 51 and the second power supply 52 are configured as power supplies capable of switching the polarity of the voltage to be output. Each of the first power supply 51 and the second power supply 52 may be a bipolar power supply capable of successively outputting either a positive voltage or a negative voltage.

Hereinafter, reference will be made to FIGS. 6A, 6B, 6C, 7A, 7B, 7C, 7D, 8A, and 8B, in conjunction with FIG. 1. These drawings are timing charts relating to the plasma processing apparatus according to the exemplary embodiment. Specifically, each of FIGS. 6A, 7A, and 8A illustrates an exemplary timing chart for the electric bias energy. FIGS. 6B, 6C, 7B, 7C, and 7D each illustrate an exemplary timing chart of a potential P41 of the first baffle plate 41, a potential P42 of the second baffle plate 42, and a plasma potential PP. FIG. 8B is an exemplary timing chart of the potential P41 of the first baffle plate 41 and the potential P42 of the second baffle plate 42.

As illustrated in FIGS. 6A, 7A, and 8A, the waveform cycle CY includes a positive phase period PI and a negative phase period NI. In the positive phase period PI, a potential of the substrate W is higher than an average potential of the substrate W in the waveform cycle CY. In the negative phase period NI, the potential of the substrate W is lower than the average potential of the substrate W in the waveform cycle CY. The potential of the substrate W mainly changes according to the electric bias energy BE.

The plasma potential PP changes according to the electric bias energy BE or the potential of the substrate W. The plasma potential PP is high in the positive phase period PI, and the plasma potential PP is low in the negative phase period NI.

In at least a partial period of the waveform cycle CY, the value of the voltage that is applied to the second baffle plate 42 by the second power supply 52 is higher than the value of the voltage that is applied to the first baffle plate 41 by the first power supply 51. Therefore, as illustrated, in at least a partial period of the waveform cycle CY, the potential P42 of the second baffle plate 42 is higher than the potential P41 of the first baffle plate 41.

When the potential P42 of the second baffle plate 42 is higher than the potential P41 of the first baffle plate 41, a flow of positive ions from the plasma in the processing space 10sp from the first baffle plate 41 toward the second baffle plate 42 is suppressed. Therefore, it is possible to suppress the diffusion of the charged particles from the processing space 10sp into the exhaust space 10se.

At least one of the voltage that is applied to the first baffle plate 41 by the first power supply 51 and the voltage that is applied to the second baffle plate 42 by the second power supply 52 may have a waveform that follows the waveform of the plasma potential PP. In this case, at least one of the first power supply 51 and the second power supply 52 is synchronized with the bias power supply 32 by a synchronization signal, and outputs the voltage having the waveform that follows the waveform of the plasma potential PP. Alternatively, the value of one the voltage that is applied to the first baffle plate 41 by the first power supply 51 and the voltage that is applied to the second baffle plate 42 by the second power supply 52 may be constant, as illustrated in FIGS. 6B, 6C, 7D, and 8B.

In one embodiment, as illustrated in FIGS. 6B and 8B, in the negative phase period NI, the value of the voltage that is applied to the second baffle plate 42 by the second power supply 52 is higher than the value of the voltage that is applied to the first baffle plate 41 by the first power supply 51. Therefore, in the negative phase period NI, the potential P42 of the second baffle plate 42 is higher than the potential P41 of the first baffle plate 41. In the positive phase period PI, the value of the voltage that is applied to the second baffle plate 42 by the second power supply 52 is lower than the value of the voltage that is applied to the first baffle plate 41 by the first power supply 51. Therefore, in the positive phase period PI, the potential P42 of the second baffle plate 42 is lower than the potential P41 of the first baffle plate 41. In the entirety of the waveform cycle CY, the value of the voltage that is applied to the first baffle plate 41 by the first power supply 51 and the value of the voltage that is applied to the second baffle plate 42 by the second power supply 52 are positive values. Therefore, in the entirety of the waveform cycles CY, the potential P42 of the second baffle plate 42 is higher than the ground potential of the chamber 10. The voltage that is applied to the first baffle plate 41 by the first power supply 51 has the waveform that follows the waveform of the plasma potential PP. The value of the voltage that is applied to the second baffle plate 42 by the second power supply 52 is constant.

In each of the embodiments illustrated in FIGS. 6B and 8B, the flow of positive ions from the plasma in the processing space 10sp from the first baffle plate 41 toward the second baffle plate 42 is suppressed in the negative phase period NI. Further, in the negative phase period NI, secondary electrons that may be emitted from the first baffle plate 41 are captured by the second baffle plate 42, so that a flow of the secondary electrons into the exhaust space 10se is suppressed.

In another embodiment, as illustrated in FIG. 6C, the value of the voltage that is applied to the second baffle plate 42 by the second power supply 52 is higher than the value of the voltage that is applied to the first baffle plate 41 by the first power supply 51 in the entirety of the waveform cycle CY. Therefore, in the entirety of the waveform cycle CY, the potential P42 of the second baffle plate 42 is higher than the potential P41 of the first baffle plate 41. In the entirety of the waveform cycle CY, the value of the voltage that is applied to the first baffle plate 41 by the first power supply 51 and the value of the voltage that is applied to the second baffle plate 42 by the second power supply 52 are positive values. Therefore, in the entirety of the waveform cycles CY, the potential P42 of the second baffle plate 42 is higher than the ground potential of the chamber 10. The voltage that is applied to the first baffle plate 41 by the first power supply 51 has the waveform that follows the waveform of the plasma potential PP. The value of the voltage that is applied to the second baffle plate 42 by the second power supply 52 is constant.

In the embodiment illustrated in FIG. 6C, the flow of positive ions from the plasma in the processing space 10sp from the first baffle plate 41 toward the second baffle plate 42 is suppressed in the entirety of the waveform cycle CY. Further, in the entirety of the waveform cycle CY, the secondary electrons that may be emitted from the first baffle plate 41 are captured by the second baffle plate 42, so that the flow of the secondary electrons into the exhaust space 10se is suppressed.

In still another embodiment, as illustrated in FIG. 7B, the value of the voltage that is applied to the second baffle plate 42 by the second power supply 52 is higher than the value of the voltage that is applied to the first baffle plate 41 by the first power supply 51 in the entirety of the waveform cycle CY. Therefore, in the entirety of the waveform cycle CY, the potential P42 of the second baffle plate 42 is higher than the potential P41 of the first baffle plate 41. In the entirety of the waveform cycle CY, the value of the voltage that is applied to the second baffle plate 42 by the second power supply 52 is a positive value. Therefore, in the entirety of the waveform cycles CY, the potential P42 of the second baffle plate 42 is higher than the ground potential of the chamber 10. The value of the voltage that is applied to the first baffle plate 41 by the first power supply 51 is a negative value in the negative phase period NI and is a positive value in the positive phase period PI. The voltage that is applied to the first baffle plate 41 by the first power supply 51 and the voltage that is applied to the second baffle plate 42 by the second power supply 52 have the waveform that follows the waveform of the plasma potential PP.

In the embodiment illustrated in FIG. 7B, the flow of positive ions from the plasma in the processing space 10sp from the first baffle plate 41 toward the second baffle plate 42 is suppressed in the entirety of the waveform cycle CY. Further, in the entirety of the waveform cycle CY, the secondary electrons that may be emitted from the first baffle plate 41 are captured by the second baffle plate 42, so that the flow of the secondary electrons into the exhaust space 10se is suppressed.

In still another embodiment, as illustrated in FIG. 7C, the value of the voltage that is applied to the second baffle plate 42 by the second power supply 52 is higher than the value of the voltage that is applied to the first baffle plate 41 by the first power supply 51 in the entirety of the waveform cycle CY. Therefore, in the entirety of the waveform cycle CY, the potential P42 of the second baffle plate 42 is higher than the potential P41 of the first baffle plate 41. In the entirety of the waveform cycle CY, the value of the voltage that is applied to the first baffle plate 41 by the first power supply 51 and the value of the voltage that is applied to the second baffle plate 42 by the second power supply 52 are positive values. Therefore, in the entirety of the waveform cycles CY, the potential P42 of the second baffle plate 42 is higher than the ground potential of the chamber 10. The voltage that is applied to the first baffle plate 41 by the first power supply 51 and the voltage that is applied to the second baffle plate 42 by the second power supply 52 have the waveform that follows the waveform of the plasma potential PP.

In the embodiment illustrated in FIG. 7C, the flow of positive ions from the plasma in the processing space 10sp from the first baffle plate 41 toward the second baffle plate 42 is suppressed in the entirety of the waveform cycle CY. Further, in the entirety of the waveform cycle CY, the secondary electrons that may be emitted from the first baffle plate 41 are captured by the second baffle plate 42, so that the flow of the secondary electrons into the exhaust space 10se is suppressed.

In still another embodiment, as illustrated in FIG. 7D, the value of the voltage that is applied to the second baffle plate 42 by the second power supply 52 is higher than the value of the voltage that is applied to the first baffle plate 41 by the first power supply 51 in the positive phase period PI. Therefore, in the positive phase period PI, the potential P42 of the second baffle plate 42 is higher than the potential P41 of the first baffle plate 41. In the negative phase period NI, the value of the voltage that is applied to the second baffle plate 42 by the second power supply 52 is lower than the value of the voltage that is applied to the first baffle plate 41 by the first power supply 51. Therefore, in the negative phase period NI, the potential P42 of the second baffle plate 42 is lower than the potential P41 of the first baffle plate 41. In the entirety of the waveform cycle CY, the value of the voltage that is applied to the first baffle plate 41 by the first power supply 51 and the value of the voltage that is applied to the second baffle plate 42 by the second power supply 52 are positive values. Therefore, in the entirety of the waveform cycles CY, the potential P42 of the second baffle plate 42 is higher than the ground potential of the chamber 10. The voltage that is applied to the second baffle plate 42 by the second power supply 52 has a waveform that follows the waveform of the plasma potential PP. The value of the voltage that is applied to the first baffle plate 41 by the first power supply 51 is constant.

In the embodiment illustrated in FIG. 7D, the flow of positive ions from the plasma in the processing space 10sp from the first baffle plate 41 toward the second baffle plate 42 is suppressed in the positive phase period PI. Further, in the positive phase period PI, secondary electrons that may be emitted from the first baffle plate 41 are captured by the second baffle plate 42, so that a flow of the secondary electrons into the exhaust space 10se is suppressed.

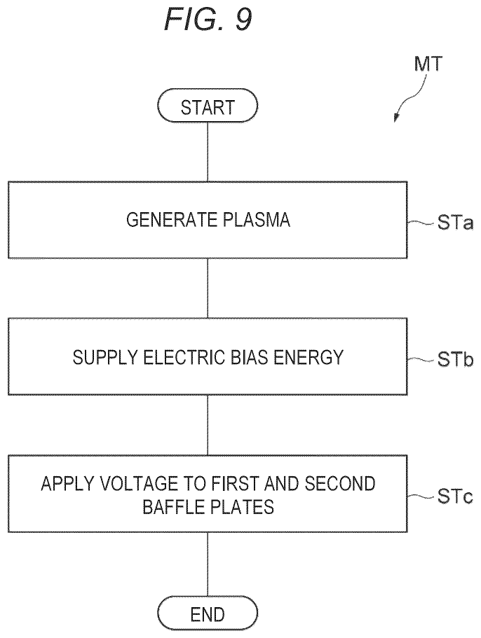

Hereinafter, FIG. 9 will be referred to. FIG. 9 is a flowchart of a plasma processing method according to an exemplary embodiment. The plasma processing method illustrated in FIG. 9 (hereinafter referred to as a “method MT”) may be applied to the plasma processing apparatus 1. The method MT includes step STa to step STc.

In step STa, the plasma is generated in the chamber 10. In step STa, the gas from the gas supply 20 is supplied to the processing space 10sp. In step STa, the pressure in the chamber 10 is reduced to a designated pressure by the exhaust system 40. In step STa, the plasma generator 12 generates the plasma from the gas in the processing space 10sp. In one embodiment, the source radio-frequency power RF from the radio-frequency power supply 31 is supplied to the radio-frequency electrode.

Step STb is performed when the plasma is generated in step STa. In step STb, the electric bias energy BE is supplied to the substrate support 11.

Step STc is performed when the electric bias energy BE is supplied to the substrate support 11 in step STb. In step STc, the voltage is applied to each of the first baffle plate 41 and the second baffle plate 42 as described above. As described above, in at least a partial period of the waveform cycle CY, the value of the voltage that is applied to the second baffle plate 42 is higher than the value of the voltage that is applied to the first baffle plate 41.

While various exemplary embodiments have been described above, various additions, omissions, substitutions and changes may be made without being limited to the exemplary embodiments described above. Also, the other embodiments may be formed by combining elements in different embodiments.

For example, the exhaust space 10se may be provided laterally with respect to the processing space 10sp or above the processing space 10sp.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing apparatus comprising:
a chamber including:
a processing space; and
an exhaust space;
an exhaust system connected to the exhaust space;
a substrate support provided in the chamber, the substrate support being configured to receive a substrate to be processed;
a plasma generator configured to generate plasma from a gas in the chamber;
a bias power supply configured to periodically supply an electric bias energy having a waveform cycle to the substrate support;
a first power supply electrically connected to the first baffle plate; and
a second power supply electrically connected to the second baffle plate, wherein
the first baffle plate is disposed in the chamber between the processing space and the second baffle plate,
the second baffle plate is disposed in the chamber between the exhaust space and the first baffle plate, and
in at least a partial period in the waveform cycle, a value of a voltage that is applied to the second baffle plate by the second power supply is higher than a value of a voltage that is applied to the first baffle plate by the first power supply.

2. The plasma processing apparatus of claim 1, wherein
in an entirety of the waveform cycle, the value of the voltage that is applied to the second baffle plate by the second power supply is higher than the value of the voltage that is applied to the first baffle plate by the first power supply.

3. The plasma processing apparatus of claim 1, wherein
the waveform cycle includes a positive phase period in which a potential of the substrate is higher than an average potential of the substrate in the waveform cycle, and a negative phase period in which the potential of the substrate is lower than the average potential, and
in the negative phase period, the value of the voltage that is applied to the second baffle plate by the second power supply is higher than the value of the voltage that is applied to the first baffle plate by the first power supply.

4. The plasma processing apparatus according to claim 2, wherein
the value of the voltage that is applied to the second baffle plate by the second power supply is constant.

5. The plasma processing apparatus of claim 1, wherein
the waveform cycle includes a positive phase period in which a potential of the substrate is higher than an average potential of the substrate in the waveform cycle, and a negative phase period in which the potential of the substrate is lower than the average potential, and
in the positive phase period, the value of the voltage that is applied to the second baffle plate by the second power supply is higher than the value of the voltage that is applied to the first baffle plate by the first power supply.

6. The plasma processing apparatus according to claim 5, wherein
the value of the voltage that is applied to the first baffle plate by the first power supply is constant.

7. The plasma processing apparatus according to claim 1, wherein
the chamber is grounded, and
in the waveform cycle, a potential of the second baffle plate is higher than a potential of the chamber.

8. The plasma processing apparatus according to claim 1, wherein
the first baffle plate and the second baffle plate extend between an outer periphery of the substrate support and a sidewall of the chamber.

9. The plasma processing apparatus according to claim 1, wherein
at least one of the first baffle plate and the second baffle plate is movable.

10. The plasma processing apparatus according to claim 1, wherein
the electric bias energy is a bias radio-frequency power having a frequency that is a reciprocal of a time length of the waveform cycle, or is a pulse of a voltage that is periodically applied to the substrate support at a time interval equal to the time length of the waveform cycle.

11. A plasma processing method comprising:
generating plasma in a chamber of a plasma processing apparatus;
supplying an electric bias energy having a waveform cycle to a substrate support disposed in the chamber; and
applying a voltage to each of a first baffle plate and a second baffle plate disposed in the chamber, wherein
the first baffle plate is disposed between a processing space in the chamber in which a substrate disposed on the substrate support is processed and the second baffle plate,
the second baffle plate is disposed between an exhaust space in the chamber to which an exhaust system is connected and the first baffle plate, and
in at least a partial period in the waveform cycle, a value of the voltage that is applied to the second baffle plate is higher than a value of the voltage that is applied to the first baffle plate.

12. The plasma processing method of claim 11, wherein
in an entirety of the waveform cycle, the value of the voltage that is applied to the second baffle plate by the second power supply is higher than the value of the voltage that is applied to the first baffle plate by the first power supply.

13. The plasma processing method of claim 11, wherein
the waveform cycle includes a positive phase period in which a potential of the substrate is higher than an average potential of the substrate in the waveform cycle, and a negative phase period in which the potential of the substrate is lower than the average potential, and
in the negative phase period, the value of the voltage that is applied to the second baffle plate by the second power supply is higher than the value of the voltage that is applied to the first baffle plate by the first power supply.

14. The plasma processing method according to claim 12, wherein
the value of the voltage that is applied to the second baffle plate by the second power supply is constant.

15. The plasma processing method of claim 11, wherein
the waveform cycle includes a positive phase period in which a potential of the substrate is higher than an average potential of the substrate in the waveform cycle, and a negative phase period in which the potential of the substrate is lower than the average potential, and
in the positive phase period, the value of the voltage that is applied to the second baffle plate by the second power supply is higher than the value of the voltage that is applied to the first baffle plate by the first power supply.

16. The plasma processing method according to claim 15, wherein
the value of the voltage that is applied to the first baffle plate by the first power supply is constant,
the chamber is grounded, and
in the waveform cycle, a potential of the second baffle plate is higher than a potential of the chamber.

17. The plasma processing method according to claim 1, wherein
the first baffle plate and the second baffle plate extend between an outer periphery of the substrate support and a sidewall of the chamber, and
at least one of the first baffle plate and the second baffle plate is movable.

18. The plasma processing method according to claim 1, wherein
the electric bias energy is a bias radio-frequency power having a frequency that is a reciprocal of a time length of the waveform cycle, or is a pulse of a voltage that is periodically applied to the substrate support at a time interval equal to the time length of the waveform cycle.

19. A plasma processing apparatus comprising:
a chamber including:
a processing space; and
an exhaust space;
a substrate support provided in the chamber, the substrate support being configured to receive a substrate to be processed;
a plasma generator configured to generate plasma from a gas in the chamber;
a bias power supply configured to periodically supply an electric bias energy having a waveform cycle to the substrate support;
a first baffle plate disposed at least partially in the processing space;
a second baffle plate disposed at least partially in the exhaust space;
a first power supply electrically connected to the first baffle plate; and
a second power supply electrically connected to the second baffle plate, wherein
each the first baffle plate and the second baffle plate are provided with a plurality of through-holes, and
in at least a partial period in the waveform cycle, a value of a voltage that is applied to the second baffle plate by the second power supply is higher than a value of a voltage that is applied to the first baffle plate by the first power supply.

20. The plasma processing apparatus according to claim 19, wherein the waveform cycle includes a positive phase period in which a potential of the substrate is higher than an average potential of the substrate in the waveform cycle, and a negative phase period in which the potential of the substrate is lower than the average potential,
in the positive phase period, the value of the voltage that is applied to the second baffle plate by the second power supply is higher than the value of the voltage that is applied to the first baffle plate by the first power supply, and
in the negative phase period, the value of the voltage that is applied to the second baffle plate by the second power supply is higher than the value of the voltage that is applied to the first baffle plate by the first power supply.
